(19) United States
(12) Patent Application Publication
(10) Pub. No.: US 2021/0140816 A1
(43) Pub. Date: May 13, 2021

(54) LIGHT SENSING APPARATUS AND APPARATUS HAVING IN-PLANE AND OUT-OF-PLANE MOTION

(71) Applicant: Innovative Interface Laboratory Corp., Hsinchu (TW)

(72) Inventor: YU-WEN HSU, Taipei (TW)

(21) Appl. No.: 17/091,204

(22) Filed: Nov. 6, 2020

Related U.S. Application Data
(60) Provisional application No. 62/931,926, filed on Nov. 7, 2019.

(51) Int. Cl. G01J 1/04; G01J 1/42

(52) U.S. Cl. CPC G01J 1/0403; H04N 5/2253; G01J 1/42; G01J 1/0488

(57) ABSTRACT

A light sensing apparatus is disclosed. The light sensing apparatus, includes a sensor configured for sensing a light; an in-plane motion motor, including a circuit board having a first bottom base with an central cavity and a circuit board frame disposed thereon, wherein the first bottom base has a first bottom surface; a lead frame disposed inside the central cavity and having a second bottom surface; and an in-plane motion actuator having a movable inner frame and a fixed outer frame both allocated in a reference plane, wherein the movable inner frame moves along at least one of two directions perpendicular to each other and parallel to the first bottom surface; and an out-of-plane motion motor, including: a base plate having a base plate surface and a base plate frame disposed on a periphery of the base plate surface; four single-axis actuators disposed on the base plate surface, each of which has an actuating end, and each of which moves the respective actuating end along a direction perpendicular to the base plate surface, wherein the first bottom surface is attached to the base plate frame, and the second bottom surface is attached to the four actuating ends.

### CROSS-REFERENCE TO RELATED APPLICATION AND CLAIM OF PRIORITY

This application claims the benefit of the U.S. Provisional Patent Application No. 62/931,926, filed on Nov. 7, 2019 at the U.S. Patent and Trademark Office, the disclosures of which are incorporated herein in their entirety by reference.

### FIELD OF THE DISCLOSURE

The present disclosure is related to a light sensing apparatus. More specifically, the present disclosure is related to a light sensing apparatus having in-plane and out-of-plane motions.

### BACKGROUND OF THE DISCLOSURE

A MEMS (Microelectromechanical System) actuator has many advantages, such as small size, low cost, precise motion control, and low power consumption, which makes it suitable for applications in compact electronic device or system. However, it is quite difficult for a MEMS actuator to achieve a motion with 6 degrees of freedom (DOFs), particularly when there is a need for an auto-focus apparatus having a stroke accuracy getting smaller to around 0.5 mm. Accordingly, the present invention discloses a solution that an apparatus using MEMS actuators and the assembly method thereof are utilized to implement a silicon motor having a long stroke motion with 6 DOFs and its application for a light sensing apparatus.

In addition, the design of the optical image stabilization (OIS) in the camera provides only the vibration reduction in two dimensions, say the vertical (or z-) direction (up and down) and the horizontal (or x-) direction (left and right). The question is that no vibration reduction in the axial direction (or y-) of the lens in the camera (forward and backward) can be provided, not to mention in the tilt (including yaw, pitch and roll) directions.

Furthermore, a light sensing apparatus, such as a camera, with optical image stabilization, auto-focus and high resolution functions needs a big space to accommodate the massive optical and mechanical systems. It causes the user inconvenience to carry and operate such a big camera.

Therefore, the Applicant has disclosed a light sensing apparatus and a method for manufacturing the light sensing apparatus to improve the problems of the prior art mentioned above, and provide a light sensing apparatus with integrated and compact design suitable for all-orientation vibration reduction, auto-focus, and high resolution applications.

### SUMMARY OF THE DISCLOSURE

In accordance with one aspect of the present disclosure, it provides a light sensing apparatus, comprising: a sensor configured for sensing a light; an in-plane motion motor, including: a circuit board having a first bottom base with an central cavity and a circuit board frame disposed thereon, wherein the first bottom base has a first bottom surface; a lead frame disposed inside the central cavity and having a second bottom surface; and an in-plane motion actuator having a movable inner frame and a fixed outer frame both allocated in a reference plane, wherein the movable inner frame moves along at least one of two directions perpendicular to each other and parallel to the first bottom surface; and an out-of-plane motion motor, including: a base plate having a base plate surface and a base plate frame disposed on a periphery of the base plate surface; four single-axis actuators disposed on the base plate surface, each of which has an actuating end, and each of which moves the respective actuating end along a direction parallel to a normal direction of the base plate surface, wherein: the first bottom surface is attached to the base plate frame, and the second bottom surface is attached to the four actuating ends.

In accordance with the another aspect of the present disclosure, it provides an apparatus having in-plane and out-of-plane motions, comprising an application device configured for an application function; an in-plane motion motor mounting thereon the application device and capable of moving in three degrees of freedom with respect to a reference plane; and an out-of-plane motion motor supporting thereon the in-plane motion motor, and including three single-axis actuators, wherein: each of the three single-axis actuators has an actuating end; and the three actuating end cooperatively enable the reference plane to move in another three degrees of freedom.

In accordance with the another aspect of the present disclosure, it provides an apparatus having in-plane and out-of-plane motions, comprising an application device configured for an application function; an in-plane motion motor mounting thereon the application device and capable of moving in three degrees of freedom with respect to a reference plane; and an out-of-plane motion motor supporting thereon the in-plane motion motor, and including a first single-axis actuator, wherein: the first single-axis actuator has an actuating end, and the actuating end enables the reference plane to move in a fourth degree of freedom other than the three degrees of freedom.

The above objectives and advantages of the present disclosure will become more readily apparent to those ordinarily skilled in the art after reviewing the following detailed descriptions and accompanying drawings, in which:

### BRIEF DESCRIPTION OF THE DRAWINGS

FIG. 1 is a schematic exploded view drawing showing a light sensing apparatus according to one embodiment of the present invention.

FIG. 2 is a schematic drawing showing an in-plane motion motor according to one embodiment of the present invention.

FIG. 3 is a schematic drawing showing in-plane motion actuator according to one embodiment of the present invention.

FIG. 4 is a top view of a micro-electromechanical actuator according to an embodiment of the present invention.

FIG. 5 is a cross-sectional view of FIG. 4 along the dotted line AA.

FIGS. 6A and 6B show the assembling state of the present invention.

FIG. 7 is a partially enlarged view of FIG. 4.

FIG. 8 is a top view of a micro-electromechanical actuator according to another embodiment of the present invention.

FIG. 9A is a schematic drawing showing an out-of-plane motion motor according to one embodiment of the present invention.

FIG. 9B is a schematic drawing showing a cross-section of an out-of-plane motion motor shown in FIG. 9A according to one embodiment of the present invention.

FIG. 10 shows the schematic top view of an embodiment of the single-axis actuator of the present invention.

FIG. 11 is a schematic sectional view of the single-axis actuator along the section line A-A′ in FIG. 10.

FIG. 12A shows an example of the relationship of the second projection area and the first area.

FIG. 12B shows another example of the relationship of the second projection area and the first area.

FIG. 12C shows an example of the position of the second cavity.

FIG. 13A shows an example in which the center of gravity of the carried object aligns the center of gravity of the single-axis actuator without the T-bar and the fulcrum hinge.

FIG. 13B shows an example in which the center of gravity of the carried object does not align the center of gravity of the single-axis actuator without the T-bar and the fulcrum hinge.

FIG. 13C shows an embodiment of the present invention with both the fulcrum hinge and the T-bar.

FIGS. 14A and 14B show the schematic top views of two additional embodiments of the fulcrum hinge.

FIG. 15A shows schematically the chip arrangement on the actuator wafer.

FIG. 15B is a schematic sectional view along the section line B-B′ in FIG. 14A.

FIG. 15C illustrates a protective material coated on the actuator wafer for fixing the movable structures for wafer cutting.

FIG. 16 is a schematic exploded view drawing showing a single-axis motor module assembled with a PCB according to one embodiment of the present invention.

FIGS. 17A and 17B are schematic drawings each of which is showing the assembly of a single-axis motor module assembled with a base plate according to one embodiment of the present invention.

FIG. 18 is a block diagram showing a method for manufacturing an apparatus having in-plane and out-of plane motions according to one embodiment of the present invention.

FIG. 19 is a block diagram showing a process of Step S1920 in FIG. 18 for providing an in-plane motion motor according to one embodiment of the present invention

FIG. 20 is a block diagram showing a process of Step S1930 in FIG. 18 for providing an out-of-plane motion motor according to one embodiment of the present invention

FIG. 21 is a block diagram showing a method for assembling an in-plane motion motor with an out-of-plane motion motor according to another embodiment of the present invention.

FIG. 22 is a block diagram showing a bonding process for electrically connecting the lead frame, the circuit board and the functional device, electrically connecting the lead frame to the circuit board, electrically connecting the in-plane motion actuator to the lead frame, and electrically connecting the sensor to the movable inner frame of the in-plane motion actuator, as shown in FIGS. 1-3 according to one embodiment of the present invention.

FIG. 23 is a block diagram showing a method for manufacturing an apparatus having in-plane and out-of plane motions according to another embodiment of the present invention.

### DETAILED DESCRIPTION OF THE EMBODIMENTS

The present disclosure will now be described more specifically with reference to the following embodiments. It is to be noted that the following descriptions of embodiments of the present disclosure are presented herein for the purposes of illustration and description only; they are not intended to be exhaustive or to be limited to the precise form disclosed.

Apparatus Having in-Plane and Out-of Motions

FIG. 1 is a schematic exploded drawing showing a light sensing apparatus according to one embodiment of the present invention. As shown in FIG. 1, the image sensing apparatus 7000 includes an in-plane motion motor 7030 and an out-of plane motion motor 7040. The in-plane motion motor 7030 provides a function capable of incrementally moving a functional device 7020 in a reference plane that the functional device 7020 lies in. The out-of-plane motion motor 7040 provides a function capable of moving the functional device 7020 by at least one single-axis motion motor 7045 in a direction vertical to the plane that the functional device 7020 lies in. The functional device 7020 can be a sensor configured for a sensing function, a mirror configured for a scanning function, or an additional filter configured for a filtering function. In case the functional device 7020 is a sensor configured for sensing a light or an image, the sensor can be a CMOS sensor used in a camera or an image sensor, for example. In the case that the functional device 7020 is applied to the image sensing apparatus 7000 and moved by two or three single-axis motion motors 7045, the plane that the functional device 7020 lies in can be tilted. In the case when the functional device 7020 is moved by four single-axis motion motors 7045, the plane that the functional device 7020 lies in can additionally be vertically moved, pitched and/or rolled. A lead frame 7032 is required to accommodate and electrically connect to the in-plane motion actuator 7031 through a first set of wires (not shown). The image sensing apparatus 7000 can further includes an application device 7010 being a filter or a lens for allowing a light having wavelengths within a predetermined range to pass therethrough. The functional device 7020 is selected depending on the application function required for the application device 7010.

FIG. 2 is a schematic drawing showing an in-plane motion motor according to one embodiment of the present invention. FIG. 3 is a schematic drawing showing an in-plane motion actuator according to one embodiment of the present invention. As shown in FIGS. 2 and 3, the in-plane motion motor 7030 includes a first circuit board 7033 having a first bottom base 1521 with a central cavity 7035 and a first circuit board frame 7037 disposed thereon, a lead frame 7032 disposed inside the central cavity 7035, and an in-plane motion actuator 7031 having a movable inner frame 1571 and a fixed outer frame 1572. The surfaces of both of the movable inner frame 1571 and the fixed outer frame 1752 are allocated in a reference plane 160, wherein the movable inner frame 1571 moves along at least one of two directions X1 and Y1 perpendicular to each other in the reference plane 160 and parallel to the first bottom surface 1521 of the first bottom base 7034. The in-plane motion actuator 7031 is disposed inside the lead frame 7032, and the functional device 7020 is disposed on the in-plane motion actuator 7031. If the in-plane motion motor 7030 is assembled in the light sensing apparatus 7000 according to one embodiment of the present invention, the structure of the first circuit board 7033 cooperates with and fits to the structure of the out-of-plane motion motor 7040.

As shown in FIGS. 1-3, four sets of the connecting elements 1573 are installed at the periphery of the movable inner frame 1571, and between the movable inner frame 1571 and the fixed outer frame 1572. Each of the four sets of the connecting elements 1573 can be a set of soft electrical linkages (SELs) mechanically connecting the movable inner frame 1571 to the fixed outer frame 1572, and electrically connecting the bonding pads 1574 on the movable inner frame 1571 to the bonding pads 1575 on the fixed outer frame 1572, directly or indirectly. In another embodiment according to the present invention, each of the four sets of the connecting elements 1773 can be integrated into a flexible circuit board mechanically connecting the movable inner frame 1571 to the fixed outer frame 1572 and electrically as well as thermally connecting the bonding pads 1574 on the movable inner frame 1571 to the bonding pads 1575 on the fixed outer frame 1572, directly or indirectly. In this case, in addition to the purposes of the electric conduction, the flexible circuit board can further transfer and dissipate the heat generated from the functional device 7020 to a heat sink disposed on the base plate 851 through the flexible circuit board, and the circuits (not shown) as well as the wire connections (not shown) disposed between the functional device 7020 and the base plate 851, to prevent the functional device 7020 from overheating during operation.

In addition, as shown in FIGS. 1-3, the lead frame 7032 has four flexible hinges 1552 each of which is located at one of the four corners, and is to be fixed to one of four notches 7036 arranged on the four corners in the central cavity 7035 of the bottom base 7034 of the first circuit board 7033 by a process such as welding. Each of the four flexible hinges 1552 provides a feasibility of moving the lead frame 7032 vertical to the plane that the functional device 7020 lies in, so that the lead frame 7032 is free from the first bottom surface 1521 of the first circuit board 7033 when it is actuated by at least one of the four single-axis motion motors 7045. The functional device 7020 is fixed on the movable inner frame 1571 of the in-plane motion motor 7030. The signal I/O pads (not shown) of the functional device 7020 are wired and electrically connected to the bonding pads 1574 on the movable inner frame 1571. The bonding pads 1575 on the fixed outer frame 1572 of the in-plane motion actuator 7031 are wired and electrically connected to the bonding pads 1553 on the lead frame 7032 by bonding a first set of wires (not shown) therebetween. The bonding pads 1553 on the lead frame 7032 are wired and electrically connected to the bonding pads (not shown) on the first circuit board 7033 by bonding a second set of wires therebetween. The bonding pads 1575 on the fixed outer frame 1572, the bonding pads 1574 on the movable inner frame 1571, and the bonding pads 1553 on the lead frame 7032, and the bonding pads (not shown) on the first circuit board 7033 are designed as required. The wire connections (not shown) between different bonding pads, such as those between the functional device 7020 and the movable inner frame 1571 and between the fixed outer frame 1572 and the lead frame 155 are for providing signals and bias for control needs. The wire connections can be done by a bonding process with an assistance of a jig or tooling properly designed.

In-Plane Motion Motor Including an in-Plane Motion Actuator Having a Built-in Single-Axis Actuator (Type 1)

Please refer to FIGS. 4 and 5 simultaneously, wherein FIG. 4 is a top view of a micro-electromechanical actuator according to an embodiment of the present invention, and FIG. 5 is a cross-sectional view of FIG. 4 along the dotted line AA. The micro-electromechanical actuator includes a substrate 1, a first frame 4, and a second frame 6. The first frame 4 and the second frame 6 are formed on the substrate 1, and the second frame 6 surrounds the first frame 4. The first frame 4 serves as a supporting structure, and the second frame 6 serves as a peripheral structure. The first frame 4 serves as a movable element, and is connected to a fixing portion 2 via resilient elements 3. The fixing portion 2 can be an anchor which is connected to the substrate 1. It can be clearly seen in FIG. 4 that the present invention adopts a central fixing portion (anchor) structure, and each resilient element 3 is connected to four corners of the first frame 4. Therefore, when the resilient elements 3 suffer the compressing force, the restoring force thereof is applied to the corners of the first frame 4, thereby expand the first frame 4 to maintain the original shapes of edges of the first frame 4, which are usually perfectly straight. The present invention further includes four micro-electromechanical actuator units 5. Each micro-electromechanical actuator unit has a first comb finger unit 5a fixed on the anchor 2, i.e. indirectly fixed on the substrate 1. Each micro-electromechanical actuator unit 5 further includes a first counter comb finger unit 5a′ fixed on the first frame 4. That is, the first comb finger unit 5a and the first counter comb finger unit 5a′ are disposed in pairs. The comb fingers of the first comb finger unit 5a directly face the finger slits of the first counter comb finger unit 5a′. Similarly, the comb fingers of the first counter comb finger unit 5a′ directly face the finger slits of the first comb finger unit 5a. When the electrostatic force is generated, the first comb finger unit 5a and the first counter comb finger unit 5a′ attract each other so that the comb fingers of the first comb finger unit 5a and those of the first counter comb finger unit 5b′ are staggered. The first comb finger unit 5a and the first counter comb finger unit 5a′ serve as an actuating unit. For the lower micro-electromechanical actuator unit 5, when the electrostatic force is generated through electrifying, the first comb finger unit 5a and the first counter comb finger unit 5a′ attract each other, thereby causing the first frame 4 to move upward. In addition, because the electrostatic force passes through a center point RA of the first frame 4, the first frame 4 does not rotate. For the same reason, when the upper micro-electromechanical actuator unit 5 is electrified to generate the electrostatic force, the first frame 4 moves downward; when the left micro-electromechanical actuator unit 5 is electrified to generate the electrostatic force, the first frame 4 moves to the right; and when the right micro-electromechanical actuator unit 5 is electrified to generate the electrostatic force, the first frame 4 moves to the left. Moreover, the micro-electromechanical actuator unit 5 further includes a sensing comb finger unit 5b. The sensing comb finger unit 5b is located opposite the first counter comb finger unit 5a′ to sense the capacitance value between the first counter comb finger unit 5a′ and the sensing comb finger unit 5b when the first frame 4 moves. Then, the capacitance value is converted to the distance between the first counter comb finger unit 5a′ and the sensing comb finger unit 5b, thereby confirming the distance that the first frame 4 moves. The sensing comb finger unit 5b and the first counter comb finger unit 5a′ serve as another actuating unit, and the first counter comb finger unit 5a′ serves as a position sensing capacitor. In addition, the first frame 4 usually serves as a carrier, on which an electronic element (not shown) is fixed. Therefore, for electrical connection, a plurality of bonding pads 40 are further disposed on the first frame 4. For the same reason, the substrate 1 also has a plurality of bonding pads 10, and the second frame 6 also has a plurality of bonding pads 60. The purposes of the bonding pads 40, 10, 60 will be illustrated in FIGS. 6A and 6B. Furthermore, in order to electrically connect the first frame 4 with the second frame 6, and also to enable the first frame 4 to move freely in the second frame 6, the first frame 4 is electrically connected to the second frame 6 via a plurality of flexible elements 7. Each flexible element 7 is formed together with the first frame 4 and the second frame 6, and usually mainly composed of silicon with a conductive metal layer in between. When viewed from above, each flexible element 7 is roughly zigzag from left to right, but its thickness is roughly identical to that of the first frame 4. Through a larger thickness of each flexible element 7, the effect of immunity in the Z-axis direction is achieved. In addition, please see the lower left corners of the first frame 4, the second frame 6, and the substrate 1. In the present invention, in order to prevent the first frame 4 and the second frame 6 from being damaged due to accidental shaking, excessive displacement distance, and other uncertain conditions, a spacer 41 is disposed on the first frame 4. The spacer 41 is usually a protrusion to prevent the first frame 4 and the second frame 6 from being too close to cause the flexible elements 7 to be excessively squeezed. Through the spacer 41, a gap can remain between the first frame 4 and the second frame 6. In addition, in order to absorb the impact force, a cushion 62 is further disposed on the second frame 6 at the position corresponding to the spacer 41. The cushion is formed via a cushioning space 61 on the second frame 6. The cushioning space 61 is a through hole so that the cushion 62 can be formed. Therefore, when the spacer 41 hits the cushion 62, the material at the position of the cushion 62 can be appropriately deformed toward the cushion space 61 to absorb the impact force.

Please refer to FIG. 5, which is a cross-sectional view of FIG. 4 along the dotted line AA. As shown in FIG. 5, the substrate 1 has cavities, whose positions can be under the micro-electromechanical actuator unit 5, or under both of the first frame 4 and the flexible elements 7, or under all of the micro-electromechanical actuator unit 5, the first frame 4, and the flexible elements 7. For ease of description, the cavity located under the micro-electromechanical actuator unit 5 is referred to as a first cavity 11, and the cavity located under both the first frame 4 and the flexible elements 7 is referred to as a second cavity 12. Moreover, in order to achieve the effect of eliminating the waste materials and residues after etching, for the first cavity 11, the upward (i.e. toward the first frame 4) projecting area thereof at least partially covers the micro-electromechanical actuator unit 5. In addition, each side of the upward projecting area of the first cavity 11 can overlap each side of the area occupied by all comb fingers of the micro-electromechanical actuator unit 5, or the perimeter of the upward projecting area of the first cavity 11 is slightly larger or smaller than that of the area occupied by all comb fingers of the micro-electromechanical actuator unit 5. For the same reason, the upward (i.e. toward the first frame 4) projecting area of the second cavity 12 at least partially covers the flexible elements 7 and the first frame 4. Furthermore, each side of the upward projecting area of the second cavity 12 can overlap each side of the area occupied by all flexible elements 7 at a certain side of the first frame 4, or the perimeter of the upward projecting area of the second cavity 12 is slightly larger or smaller than that of the area occupied by all flexible elements 7 at the certain side of the first frame 4. As mentioned above, due to the miniaturization of the size of the comb finger, the width of the finger slit between the comb fingers is very small. In addition, when the first comb finger unit 5a and the first counter comb finger unit 5a′ are staggered, the space at the finger slit of the first comb finger unit 5a becomes even narrower because a large part thereof is taken up by the first counter comb finger unit 5a anical actuator unit 5, or under both of the fthe first counter comb finger unit 5a′ also becomes even narrower because a large part thereof is taken up by the first comb finger unit 5a. Due to the existence of the first cavity 11, the waste materials and residues after etching the comb fingers will fall into the first cavity 11 and then be discharged, or at least stay in the first cavity 11 and away from the comb fingers. This enables the probability of the waste materials and residues staying between the finger slits or between the comb fingers and the substrate to be greatly reduced so that the production yield is greatly enhanced. For the same reason, because each flexible element 7 must be quite flexible, i.e. very easy to be stretched and squeezed, and its elastic restoring force is extremely low so as not to affect the movement of the first frame 4, the structure of each flexible element 7 is also extremely small. Therefore, the gap between the zigzag structures of two adjacent flexible elements 7 is also very narrow. If the waste materials and residues after etching remain, the softness of each flexible element 7 will be greatly reduced. Hence, through the disposition of the second cavity 12 of the present invention, the waste materials and residues after etching the flexible elements 7 will fall into the second cavity 12 and then be discharged, or at least stay in the second cavity 12 and away from the flexible elements 7. This enables the probability of the waste materials and residues staying in the gap between the zigzag structures of two adjacent flexible elements 7 or between each flexible element 7 and the substrate 1 to be greatly reduced so that the production yield is greatly enhanced. Furthermore, the bonding pads 10, 40, 60 are disposed on the substrate 1, the first frame body 4, and the second frame body 6 respectively. The purposes of the bonding pads 10, 40, 60 will be illustrated in FIGS. 6A and 6B.

Please refer to FIGS. 6A and 6B, which show the assembling state of the present invention. The first comb finger units 5a of the micro-electromechanical actuator units 5 (please refer to FIG. 4) are all fixed on the substrate 1 via the anchor 2. In order to avoid assembling failure or even structural damage due to the shaking of the first frame 4 during the assembling of the electronic element 8 and the wire bonding 70, a supporting body 100 is used as a jig. Supporting protrusions 100″ of the supporting body 100″ pass through the second cavity 12 to support the first frame 4, and the substrate 1 is directly placed on the supporting surface 100′. In this way, the stability of the overall structure during the assembling of the electronic element 8 and the wire bonding 70 can be ensured. Through the wire bonding 70, the bonding pads 80 are electrically connected to the bonding pads 40 of the first frame 4. In this way, signals of the electronic element 8 can be transmitted outwards, or external commands can be transmitted into the electronic element 8. Moreover, the bonding pads 40 are electrically connected to the bonding pads 60 via the flexible elements 7, the bonding pads 60 are electrically connected to the bonding pads 10 via the wire bonding process, and then the bonding pads 10 are electrically connected to the outside. For the sake of simplicity of the drawings, the first cavity 11 in FIG. 5 is not drawn in FIGS. 6A and 6B.

Please refer to FIG. 7, which is a partially enlarged view of FIG. 4. FIG. 7 mainly shows the left micro-electromechanical actuator unit 5 of the entire device in FIG. 4 and its surrounding elements. The first comb finger unit 5a of the micro-electromechanical actuator unit 5 is fixed on the anchor 2, and the first counter comb finger unit 5a′ is fixed on the first frame body 4 and corresponding to the first comb finger unit 5a. As for the sensing comb finger unit 5b, it is located opposite to the first counter comb finger unit 5a′. The effects of the above comb finger units 5a, 5a′, 5b are not repeated here. Because the first frame 4 of this embodiment can move up and down or left and right, it is possible that the first counter comb finger unit 5a′ collides with the first comb finger unit 5a and the sensing comb finger unit 5b, thereby causing damage. In order to avoid this phenomenon, in the present invention, a constraint anchor 2′ (constraint fixing portion) and a constraint hinge 31 are disposed near each micro-electromechanical actuator unit 5, and a decoupling hinge 32 is disposed between the first frame 4 and the first counter comb finger unit 5a′. The decoupling hinge 32 is fixed to the constraint hinge 31 via a decoupling point 30. Take FIG. 7 as an example, the first counter comb finger unit 5a′ is only allowed to move left and right, i.e. moving parallel to the forward and reverse directions of the X-axis, and moving forward and reversely along the finger direction of the first counter comb finger unit 5a′. Moreover, the first counter comb finger unit 5a′ must be immune to the movement parallel to the Y-axis direction, i.e. not moving in the arranging direction of the first counter comb finger unit 5a′. Similarly, the right micro-electromechanical actuator unit 5 of the entire device in FIG. 4 operates in the same way. That is, the micro-electromechanical actuator unit 5 which controls the first frame 4 to move left and right must be immune to the Y-axis direction. Furthermore, the micro-electromechanical actuator unit 5 which controls the first frame 4 to move up and down, i.e. the upper and lower micro-electromechanical actuator units 5 in FIG. 4, must be immune to the X-axis direction. Therefore, the constraint hinge 31 must be immune to the arranging direction of the first counter comb finger units 5a′. According to FIG. 7, the arranging direction of the first counter comb finger units 5a′ is an up-and-down arranging direction. However, because the first counter comb finger unit 5a′ must be able to move horizontally along the finger direction of the first counter comb finger unit 5a′, i.e. moving left and right or in the X-axis direction according to the left micro-electromechanical actuator unit 5 in FIG. 7, the constraint hinge 31 must be able to generate the elastic deformation along the finger direction of the first counter comb finger unit 5a′. Thus, the anchor 2′ must be as far away from the decoupling point 30 as possible. For the upper and lower decoupling points 30 for the first counter comb finger unit 5a′ in FIG. 7, the midpoint thereof is the position where the constraint anchor 2′ is disposed. The upper decoupling point 30, the lower decoupling point 30, and the constraint anchor 2′ are aligned in a straight line parallel to the arranging direction of the first counter comb finger unit 5a′ (the Y-axis direction). Hence, the size of the constraint hinge 31 in the finger direction of the first counter comb finger unit 5a′ (the X-axis direction) is extremely short. This causes the constraint hinge 31 to have an extremely high rigidity in the direction parallel to the arranging direction of the first counter comb finger unit 5a′ (the Y-axis direction). Therefore, when the first frame 4 moves up or down, the constraint hinge 31 can pull the decoupling point 30 tight without moving, and only the decoupling hinge 32 bends under the driving of the first frame 4. However, because the upper and lower decoupling points 30 are at a considerable distance from the constraint anchor 2′ in the Y-axis direction, the constraint hinge 31 has considerable elasticity in the X-axis direction. Hence, when the first counter comb finger unit 5a′ moves along the finger direction, the constraint hinge 31 can be pulled by the decoupling point 30 and bent. For the same reason, for the decoupling hinge 32, because it needs to bend in the direction parallel to the arranging direction of the first counter comb finger unit 5a′, it needs to have a longer characteristic length in the direction parallel to the finger direction of the first counter comb finger unit 5a′ to increase the elasticity. Oppositely, the decoupling hinge 32 cannot bend in the direction parallel to the finger direction of the first counter comb finger unit 5a′, so its characteristic length in the direction parallel to the arranging direction of the first counter comb finger unit 5a′ must be very short. That is, the connecting point between the decoupling hinge 32 and the first frame 4, the connecting point between the decoupling hinge 32 and the first counter comb finger unit 5a′, and the decoupling point 30 are aligned in a straight line parallel to the finger direction of the first counter comb finger unit 5a′ so that the decoupling hinge 31 can be immune to the bending generated by receiving the force parallel to the finger direction of the first counter comb finger unit 5a′. Therefore, when the first relative counter finger 5a′ is pulled to the right, the decoupling hinge 32 can be pulled to the right by the first relative counter finger 5a′ without deformation so that the transmission of the pulling force is not delayed, or the pulling force will not be absorbed due to the deformation of the decoupling hinge 32.

Please continue to refer to FIG. 7. In order to appropriately increase the bending ability of the constraint hinge 31 in the direction parallel to the finger direction of the first counter comb finger unit 5a′, i.e. the flexibility, the constraint hinge 31 has a folded structure. However, the folded structure of the constraint hinge 31 is still fixed to the constraint anchor 2′ and the decoupling point 30 in the direction parallel to the arranging direction of the first counter comb finger unit 5a′. For the same reason, in order to appropriately increase the bending ability of the decoupling hinge 31 in the direction parallel to the arranging direction of the first counter comb finger unit 5a′, i.e. the flexibility, the decoupling hinge 31 also has a folded structure. However, the folded structure of the decoupling hinge 31 is still fixed to the decoupling point 30 and the first frame 4 in the direction parallel to the finger direction of the first counter comb finger unit 5a′.

Please refer to FIG. 8, which is a top view of a micro-electromechanical actuator according to another embodiment of the present invention. As shown in FIG. 8, the micro-electromechanical actuator has a plurality of micro-electromechanical actuator units 5, and each micro-electromechanical actuator unit 5 has a plurality of comb finger structures. First, for the X-axis direction, a first comb finger unit 501, a second comb finger unit 502, a third comb finger unit 503, and a fourth comb finger unit 504 are connected to an anchor 2. A positive X-axis direction sensing comb finger unit 5b+x is disposed between the first comb finger unit 501 and the second comb finger unit 504, and a negative X-axis direction sensing comb finger unit 5b−x is disposed between the third comb finger unit 503 and the fourth comb finger unit 504. All comb finger units 501, 502, 503, 504, 5b+x, 5b−x are fixed to a substrate via the anchor 2 (please refer to FIG. 5). It can be seen in FIG. 8 that the electrostatic force directions of the first comb finger unit 501, the second comb finger unit 502, the third comb finger unit 503, and the fourth comb finger unit 504 all do not pass through the center point RA (rotating axis). However, because the first comb finger unit 501 and the second comb finger unit 502 are symmetrically disposed, the resultant force of the respective electrostatic forces of the first comb finger unit 501 and the second comb finger unit 502 passes through the center point RA. Similarly, because the third comb finger unit 503 and the fourth comb finger unit 504 are also symmetrically disposed, the resultant force of the respective electrostatic forces of the third comb finger unit 503 and the fourth comb finger unit 504 also passes through the center point RA. Therefore, when intending to enable the first frame 4 to move toward the positive direction of the X-axis, the first comb finger unit 501 and the second comb finger unit 502 simultaneously generate electrostatic forces to attract the first counter comb finger unit 5a′. At the same time, an inductive capacitance is generated between the positive X-axis direction sensing comb finger unit 5b+x and the first counter comb finger unit 5a′ so that the moving distance of the first frame 4 can be derived. Similarly, when intending to enable the first frame 4 to move toward the negative direction of the X-axis, the third comb finger unit 503 and the fourth comb finger unit 504 simultaneously generate electrostatic forces to attract the first counter comb finger unit 5a′. At the same time, an inductive capacitance is generated between the negative X-axis direction sensing comb finger unit 5b-x and the first counter comb finger unit 5a′ so that the moving distance of the first frame 4 can be derived. In addition, the embodiment of FIG. 8 also has the constraint anchor 2′, the constraint hinge 31, the decoupling hinge 32, and the decoupling point 30. The related connecting relationships among the constraint anchor 2′, the constraint hinge 31, the decoupling hinge 32, and the decoupling point 30 as well as the functions thereof have been described in FIG. 7, and will not be repeated here.

Please continue to refer to FIG. 8. For the Y-axis direction, a fifth comb finger unit 505, a sixth comb finger unit 506, a seventh comb finger unit 507, and an eighth comb finger unit 504 are connected to the anchor 2. A positive Y-axis direction sensing comb finger unit 5b+y is disposed between the seventh comb finger unit 507 and the eighth comb finger unit 508, and a negative Y-axis direction sensing comb finger unit 5b-y is disposed between the fifth comb finger unit 505 and the sixth comb finger unit 506. All comb finger units 505, 506, 507, 508, 5b+y, 5b-y are fixed to the substrate via the anchor 2 (please refer to FIG. 5). It can be seen in FIG. 8 that the electrostatic force directions of the fifth comb finger unit 505, the sixth comb finger unit 506, the seventh comb finger unit 507, and the eighth comb finger unit 508 all do not pass through the center point RA (rotating axis). However, because the fifth comb finger unit 505 and the sixth comb finger unit 506 are symmetrically disposed, the resultant force of the respective electrostatic forces of the fifth comb finger unit 505 and the sixth comb finger unit 506 passes through the center point RA. Similarly, because the seventh comb finger unit 507 and the eighth comb finger unit 508 are also symmetrically disposed, the resultant force of the respective electrostatic forces of the seventh comb finger unit 507 and the eighth comb finger unit 508 also passes through the center point RA. Therefore, when intending to enable the first frame 4 to move toward the positive direction of the Y-axis, the seventh comb finger unit 507 and the eighth comb finger unit 508 simultaneously generate electrostatic forces to attract the first counter comb finger unit 5a′. At the same time, an inductive capacitance is generated between the positive Y-axis direction sensing comb finger unit 5b+y and the first counter comb finger unit 5a′ so that the moving distance of the first frame 4 can be derived. Similarly, when intending to enable the first frame 4 to move toward the negative direction of the Y-axis, the fifth comb finger unit 505 and the sixth comb finger unit 506 simultaneously generate electrostatic forces to attract the first counter comb finger unit 5a′. At the same time, an inductive capacitance is generated between the negative Y-axis direction sensing comb finger unit 5b-y and the first counter comb finger unit 5a′ so that the moving distance of the first frame 4 can be derived. In addition, because the sensing comb finger and the actuating comb finger are both the application of the sensing capacitor, actually the functions of the sensing comb finger and the actuating comb finger can be replaced via software to increase the flexibility of use.

Please continue to refer to FIG. 8. Because the respective electrostatic forces of the first to the eighth comb finger units 501-508 all do not pass through the center point RA, if intending to make the first frame 4 rotate, in principle it is only necessary that one of the first to the eighth comb finger units 501-508 generates the electrostatic force, and the first frame 4 can rotate. For example, for the first, the third, the fifth, and the seventh comb finger units 501, 503, 505, 507, when one of them generates the electrostatic force, the first frame 4 can rotate clockwise. Certainly, in order to average forces, it is usually more appropriate to apply forces with the comb finger units in the diagonal direction; that is, the first comb finger unit 501 and the third comb finger unit 503 both generate electrostatic forces, or the fifth comb finger unit 505 and the seventh comb finger unit 507 both generate electrostatic forces. If in order to increase the driving force more quickly, the first comb finger unit 501, the third comb finger unit 503, the fifth comb finger unit 505, and the seventh comb finger unit 507 can all generate electrostatic forces to achieve the above effect. Similarly, for the second, the fourth, the sixth, and the eighth comb finger units 502, 504, 506, 508, when one of them generates the electrostatic force, the first frame 4 can rotate counterclockwise. Certainly, in order to average forces, it is usually more appropriate to apply forces with the comb finger units in the diagonal direction; that is, the second comb finger unit 502 and the fourth comb finger unit 504 both generate electrostatic forces, or the sixth comb finger unit 506 and the eighth comb finger unit 508 both generate electrostatic forces. If in order to increase the driving force more quickly, the second comb finger unit 502, the fourth comb finger unit 504, the sixth comb finger unit 506, and the eighth comb finger unit 508 can all generate electrostatic forces to achieve the above effect. Furthermore, the underside of each micro-electromechanical actuator unit 5 of the embodiment in FIG. 8 can have a cavity as shown in FIGS. 4 and 5 so that the waste materials and residues after etching can be discharged. The specific relationship between the cavity and the comb fingers or the flexible elements is as shown in FIG. 5 and its descriptions, and will not be repeated here.

Please continue to refer to FIG. 8. In this embodiment, the first frame 4 can also move obliquely on the XY plane. For example, for the movement toward the upper right direction, it can be achieved by the attractions generated by the pair of the first comb finger unit 501 and the eighth comb finger unit 508, or by the attractions generated by the pair of the second comb finger unit 502 and the seventh comb finger unit 507. Certainly, the movement toward the upper right direction can also be achieved by the attractions generated by the pair of the first comb finger unit 501 and the eighth comb finger unit 508, simultaneously with the attractions generated by the pair of the second comb finger unit 502 and the seventh comb finger unit 507; that is, the four comb finger units 501, 508, 502, 507 simultaneously generate electrostatic forces. Similarly, for the movement toward the lower left direction, the purpose of oblique movement is achieved by the third, the fourth, the fifth, and the sixth comb finger units 503, 504, 505, 506. As for the movement toward the upper left direction and the lower right direction, they are achieved in a similar fashion, and will not be repeated here.

In summary, through the embodiment as shown in FIG. 8, the present invention can achieve a micro-electromechanical actuating device providing a movement having multiple degrees of freedom on the plane, i.e. the horizontal movement on the XY plane (i.e. including the horizontal movement in the X-axis direction, the horizontal movement in the Y-axis direction, and the oblique and horizontal movement), and the rotation in the Z-axis direction. Through the comb finger units of the micro-electromechanical actuator anchored in the center, facing four sides, and disposed in pairs, although the directions of the electrostatic forces of the respective comb finger units of the micro-electromechanical actuator all do not pass through the center point, the supporting structure (the first frame, the inner frame, or the moving frame) can move horizontally as long as two comb finger units at the same side simultaneously operate with the same force. If only a single comb finger unit generates the electrostatic force, because the direction of the electrostatic force thereof does not pass through the center point, a force arm is formed between the electrostatic force and the center point, thereby generating a deflecting torque. In addition, by disposing a cavity on the substrate, the waste materials and residues generated during the manufacture of the actuator can be more easily discharged from the finger slits of the comb finger unit of the actuator, and from the place between the comb fingers and the substrate. Otherwise, the waste materials and residues are at least kept away from the comb fingers of the actuator so as not to affect the operation of the actuator so that the comb fingers of the actuator can be made smaller and denser, thereby enhancing the electro-mechanical converting efficiency, greatly increasing the driving force of the electrostatic force, and enhancing the yield rate. Moreover, a jig for the wire bonding is further used to support the movable part of the actuator of the present invention from below during the wire bonding so as to enhance the yield and the reliability of the wire bonding. It can be seen that the present invention has an outstanding contribution to this technical field.

Out-of-Plane Motion Motor

FIG. 9A is a schematic drawing showing an out-of-plane motion motor according to one embodiment of the present invention, and FIG. 9B is a schematic drawing showing a cross-section A-A of an out-of-plane motion motor shown in FIG. 9A. As shown in FIG. 9A, the out-of-plane motion motor 7040 includes a base plate 851 having a base plate surface 852 and a base plate frame 853 disposed on a periphery of the base plate surface 852, and four single-axis motor 7045 disposed on the base plate surface 852. Each of the single-axis motor 7045 has an single-axis actuators 854 and an actuating end 855 moving along a direction parallel to a normal direction of the base plate surface 852. The actuating end can be a T-bar 1100 as shown in FIG. 10, depending on its shape. Accordingly, the actuating ends 855 can be moved in a direction parallel to each other, individually or cooperatively. Also referring to FIGS. 1, 2, 9A and 9B, the first bottom surface 1521 of the first circuit board 7033 is attached to the base plate frame 851 of the out-of-plane motion motor 7040, and the second bottom surface 1551 of the lead frame 7032 is directly or indirectly attached to and supported by the four actuating ends 855 of the four single-axis motors 7045. Each of the four single-axis motors 7045 can further include a fulcrum hinge 700 as shown in FIG. 10. The four single-axis motors 7045 can independently control the motion displacements of the actuating ends 855, and thus the second bottom surface 1551 of the lead frame 7032 is able to move along the direction vertical to the plane that the functional device 7020 lies in and/or rotate in the pitched or rolled direction. Alternatively, according to another embodiment of the present invention, an additional plate 7041 having a top surface 7042 is further disposed on the four actuating ends 855 as a platform to support the second bottom surface 1551 of the lead frame 7032. The second bottom surface 1551 of the lead frame 7032 can be adhered to the top surface 7042 of the additional plate 7041 by applying a glue layer or adhesive so that the second bottom surface 1551 of the lead frame 7032 is moved by the four actuating ends 855 through the additional plate 7041.

FIGS. 17A and 17B are Schematic Drawings Each of which is Showing a single-axis motor assembled with a base plate according to one embodiment of the present invention. As shown in FIGS. 17A and 17B, the four single-axis actuators 6002 are cut from a substrate produced by a semiconductor process. Each of the four single-axis actuator 6002 is assembled to form a single-axis motor 6001 as shown in FIGS. 17A and 17B, and then the single-axis motor 6001 is flipped 90 degrees up and is fixed on the base plate surface 6005 of the base plate 6003 by welding the contact pads 6006 on the four single-axis motor 6001 to the metal pads (not shown) on the base plate surface 6003 or the metal pads 6007 on the base plate surface 6005 of the base plate 6003. Each of the four single-axis motors 6001 is held through two clamps 6004 fixed on the base plate surface 6003 to enhance the fixing strength of each of the four single-axis motors 7045. The metal pads (not shown) on the base plate surface 852 as shown in FIG. 9A, which metal pads are similar to the metal pads 6007 shown in FIGS. 17A and 17B, and the contact pads (not shown) on the four single-axis motors 7045 as shown in FIG. 9A, which contact pads are similar to the contact pads 6006 shown in FIGS. 17A and 17B, are designed as required. The connections between the metal pads 6007 on the base plate surface 852 or the metal pads 6007 on the base plate surface 6005 of the base plate 6003 and the contact pads 6006 on the four single-axis motors 6001 are also for providing signals and biases for control needs.

Single-Axis Actuator (Linear Actuator)

Please refer to FIGS. 10-11. FIG. 10 shows the schematic top view of an embodiment of the actuator of the present invention, namely the single-axis actuator 10000. The single-axis actuator 10000 is a linear motion actuator. FIG. 11 is a schematic sectional view of the single-axis actuator along the section line A-A′ in FIG. 10. The single-axis actuator 10000 includes a substrate 100, which has a cavity 200 and an electronic element 110. The substrate 100 has a front surface 120 and a rear surface 130, and the cavity 200 extends through the front surface 120 and the rear surface 130 in the z-direction as defined in FIG. 10. The single-axis actuator 10000 also includes a first fixed electrode structure 300 formed on the substrate 100 so that the first fixed electrode structure 300 is fixed on the substrate 100. The single-axis actuator 10000 further includes a movable electrode structure 500 connected to the substrate 100 through an elastic element 400, which may be an elastic linkage. The first fixed electrode structure 300 and the movable electrode structure 500 form a capacitor. In the embodiment shown in FIG. 10, both the first fixed electrode structure 300 and the movable electrode structure 500 are comb structures. Therefore, the first fixed electrode structure 300 has a first plurality of comb fingers 320 and the movable electrode structure 500 has a second plurality of comb fingers 520. Each of the first plurality and the second plurality of the comb fingers 320, 520 are parallel to one another. When there is no voltage applied between the first fixed electrode structure 300 and the movable electrode structure 500, the comb fingers 320 of the first fixed electrode structure 300 and the comb fingers 520 of the movable electrode structure 500 do not interdigitate. The capacitor is formed through the first plurality and the second plurality of comb fingers 320, 520. The first plurality and the second plurality of comb fingers 320, 520 are disposed above the cavity 200 to ensure the residual materials from processing can be completely removed through the cavity 200. Therefore, the size of the cavity 200 has to be sufficiently large to completely remove the residual materials; a square with side length slightly more than 10 microns would be sufficiently large. To put it another way, if one looks upward from the cavity 200 on the rear surface 130 and sees any comb finger, then the cavity 200 is sufficiently large. In the present invention, the horizontal projection area of the cavity 200 is defined as a first area 210, and the horizontal projection area of at least one of the first fixed electrode structure 300 and the movable electrode structure 500 is defined as a second projection area 350 on the substrate. FIG. 12A shows an example of the second projection area 350 on the substrate, wherein the second projection area 350 is the projection area of both the first fixed electrode structure 300 and the movable electrode structure 500. The second projection area can be the projection area of only one of the first fixed electrode structure 300 and the movable electrode structure 500. The first area 210 and the second projection area 350 overlap. By “overlap” we mean that the first area 210 and the second projection area 350 overlap a certain percentage, say at least 1% of the second projection area 350, for the size of the cavity 200 to be sufficiently large to completely remove the residual materials, as shown in FIG. 12B, wherein the second projection area 350 is the projection area of the movable electrode structure 500. Without the cavity 200, the comb fingers 320, 520 have to be sparsely arranged to remove the residual materials. But when the comb fingers 320, 520 are sparsely arranged, the efficiency of electrical-to-mechanical energy conversion is low. In other words, the voltage applied between the first fixed electrode structure 300 and the movable electrode structure 500 has to be high. Hence, the cavity 200 allows the removal of residual process contaminants and the improvement of the efficiency of electrical-to-mechanical energy conversion.

The electronic element 110 disposed on the substrate 100 represents the integration of all the motion control electronic components and circuits on the substrate 100. The single-axis actuator 10000 further includes at least one position sensing capacitor 600 formed by the movable electrode structure 500 and a second fixed electrode structure 610 formed on the substrate 100. The at least one position sensing capacitor 600 is disposed above either the cavity 200 or a second cavity of the substrate 100. If the cavity 200 also allows the removal of residual process contaminants for the at least one position sensing capacitor 600, then there is no need for the second cavity. For example, in the embodiment shown in FIG. 10, the cavity 200 is large enough to remove residual process contaminants for two position sensing capacitors 600, and there is no second cavity. When there is need, a second cavity or cavities can be disposed in the substrate 100 to remove residual process contaminants specifically for the at least one position sensing capacitor 600. For example, in the embodiment shown in FIG. 12C, the second fixed electrode structure 610 of the position sensing capacitor 600 has a horizontal projection area 650, the second cavity has a horizontal projection area 260, and the position sensing capacitor 600 is disposed above the second cavity of the substrate. The at least one position sensing capacitor 600 is used for detecting the displacement of the movable electrode structure 500.

In the embodiment shown in FIG. 10, the elastic element 400, or the elastic linkage, is called a main hinge. The main hinge has a first end, a first center point 450 and a second end, and the first and the second ends are fixed on the substrate 100. Each of the first and the second ends is fixed on the substrate 100 by a first anchor 801. The movable electrode structure 500 has a keel 510 connected with the first center point 450. The single-axis actuator 10000 further includes a fulcrum hinge 700 connected with the first center point 450 and a T-bar 1100 connected with the fulcrum hinge 700. The T-bar 1100 is adopted for easily holding the carried object attached thereon. In further applications, this single-axis actuator 10000 is designed to be flipped 90 degrees for driving a carried object to move along the out-of-plane direction. The purpose of the fulcrum hinge 700 is to resolve the issue of the carried object peeling from the T-bar 1100 when there is a shear force applied to the connecting point between the fulcrum hinge 700 and the T-bar 1100. Please see FIGS. 13A-13C. FIG. 13A shows an example in which the center of gravity of the carried object 5000 aligns the center of gravity of the single-axis actuator without the T-bar and the fulcrum hinge. In comparison, FIG. 13B shows an example in which the center of gravity of the carried object 5000 does not align the center of gravity of the single-axis actuator without the T-bar and the fulcrum hinge. In FIG. 13B, the stress concentrates on the circled area, and thus, a torque is produced. FIG. 13C shows an embodiment of the present invention with both the fulcrum hinge 700 and the T-bar 1100 to avoid the problem arising from FIG. 13B. The fulcrum hinge 700 has low stiffness in the x-direction but high stiffness in the y-direction and z-direction. In other words, the stiffness in the y-direction k_{y} is much greater than the stiffness in the x-direction kₓ, i.e. k_{y}>>kₓ, and the stiffness in the z-direction k_{z} is also much greater than the stiffness in the x-direction kₓ, i.e. k_{z}>>kₓ. High stiffness in the y-direction is necessary to avoid the decrease of displacement in the y-direction. One skilled in the art can design a variety of fulcrum hinges to meet the requirements. FIGS. 14A and 14B show the schematic top view of two embodiments of the fulcrum hinge in addition to the fulcrum hinge 700 shown in FIG. 10 or 13C. For the case without the fulcrum hinge 700, an external x-directional force applied to the carried object may generate a shear force and a moment at the boundary surface between the carried object and the T-bar 1100. The large shear force and/or the moment may cause the carried object to peel from the surface of T-bar 1100. For the case with the fulcrum hinge 700, the external x-directional force applied to the object may lead to a deformation of the fulcrum hinge 700 to reduce the shear force and the moment at the boundary surface between the carried object and the T-bar 1100. In some circumstances, the fulcrum hinge 700 can be omitted if the shear force is negligible.

The single-axis actuator 10000 further includes at least one pair of constraining hinges 900, wherein each constraining hinge of the at least one pair of constraining hinges 900 has a third end and a fourth end, the third end is connected to either the keel 510 or an outermost comb finger of the second plurality of comb fingers, and the fourth end is fixed on the substrate 100 by a second anchor 802. In the embodiment shown in FIG. 10, there are two pairs of constraining hinges 900. Through a simulation, it is seen that when the y-directional force of 0.05N is applied to the T-bar 1100, the y-directional motion travels up to 500 microns and the deformation of the main hinge still does not reach the fracture strength. In other words, the present invention can be utilized to provide large motion strokes above 500 microns in the out-of-plane direction. When the y-directional and x-directional forces are both 0.05N, the constraining hinges 900 effectively limit the off-axis motion of the movable electrode structure 500. In the Meantime, the fulcrum hinge 700 is also effectively deformed to prevent the carried object from peeling off from the surface of T-bar 1100. The force of 0.05N is equivalent to 1,020 g (g denotes one gravity) when the mass of the carried object is 5 milligrams. Thus, the single-axis actuator of the present invention can overcome the problem of the robustness of impact

The single-axis actuator 10000 further includes a support arm 1200 where the first fixed electrode structure 300 extends therefrom, wherein the support arm 1200 has a fifth end and a sixth end, and each of the fifth and the sixth ends is fixed on the substrate 100 by a third anchor 803.

The actuator wafer at this stage has a lot of chips with the movable structures. How to protect these movable structures in the chips until the actuator wafer being cut to separate the chips is a very important issue. FIGS. 15A-15C illustrate how to protect the movable structures of the single-axis actuator 10000 for wafer cutting. As shown in FIG. 15A, there is a third cavity 20500 in the substrate at the position of T-bar 1100 before the wafer cutting process. The third cavity 20500 is reserved for the motion strokes of the T-bar 1100. As shown in FIG. 15B, the actuator wafer 20000 is attached to a carrier wafer 30000. As shown in FIG. 15C, a protective material 20100 such as a photoresist or wax is coated on the actuator wafer 20000 for fixing the movable structures for wafer cutting. After the wafer cutting, the carrier wafer 30000 is separated from the actuator wafer 20000, and the protective material 20100 is removed to obtain the chips, each of which includes a single-axis actuator 10000. Both the separation of wafers and the removal of the protective material 20100 can be easily achieved by applying chemicals.

The single-axis actuator provided by the present invention allows the making of an out-of-plane motion motor with a large motion stroke, the robustness of impact, the easy removal of residual process contaminants, an improvement of the efficiency of electrical-to-mechanical energy conversion and the off-axis motion decoupling of movable comb structure.

Single-Axis Motor Module

FIG. 16 is a schematic exploded view drawing showing a single-axis motor assembled with a PCB according to one embodiment of the present invention. As shown in FIG. 16, a single-axis motor 6001 includes a single-axis actuator 6002, a rigid printing circuit board (PCB) 6003 having a metal circuitry routing (not shown) thereon and at least an amount of the metal pads 6006 and a control chip 6008 adjacent to the single-axis actuator 6002. The control chip 6008, can be an Application specific Integrated Circuits (ASIC) chip, and can be formed together with the single-axis actuator 6002 on the substrate 6009 when the single-axis actuator 6002 is produced by a photolithographic process in a semiconductor manufacturing process. The control chip 6008 electrically connects the single-axis actuator 6002 to control the actuation of the actuating end of the single-axis actuator 6002. The single-axis actuator 6002 is well aligned with and mounted on the rigid PCB 6003. In case the control chip 6008 is separately produced from the manufacturing of the single-axis actuator 6002, the control chip 6008 is placed nearby the single-axis actuator 6002 and is mounted on the PCB 6003. A wire bonding process is applied to electrically connect the single-axis actuator 6002, control chip 6008 and PCB 6009. The wire bonding process can be a welding process and is a solder paste process, for example. Two clamps (not shown) similar to those clamps 6004 as shown in FIGS. 17A and 17B can be optionally fixed on the base plate surface 6005 to hold the single-axis actuator 6002 at both ends, and to enhance the fixing strength of the single-axis actuator 6002.

FIGS. 17A and 17B are schematic drawings each of which is showing the assembly of a single-axis motor module 6000. The single-axis motor module 6000 includes one single-axis actuator 6002 and a base plate 6003. The single-axis actuator 6002 has a planar surface 6101 and a side surface 6102. If the single-axis motor module 6000 is used for an apparatus having one out-of-plane motion according to one embodiment of the present application, as shown in FIGS. 17A and 17B, the single-axis motor 6001 is welded to the base plate surface 6005 of the base plate 6003 of the single-axis motor module 6000, and the single-axis motor module 6000 is a unit apparatus for sale. If the single-axis motor module 6000 or the single-axis motor 6001 is used for an apparatus having multiple out-of-plane motions with or without the in-plane motions according to one embodiment of the present application, the single-axis motor module 6000 or the single-axis motor 6001 shown in FIGS. 16, 17A and 17B is welded to the base plate surface 852 of the base plate 851 of the out-of-plane motion motor 7040 shown in FIG. 1. In the case that the single-axis motor module 6000 is a single apparatus for sale, the contact pads 6006 on the PCB 6009 of the single-axis motor module 6000 is welded to the metal pads 6007 on the base plate 6003. A wire bonding process is applied to electrically connect the single-axis actuator 6002, control chip 6008 and the base plate 6003. The wire bonding process can be a welding process, a solder paste process, or a combination thereof, for example. Two clamps 6004 fixed on the base plate surface 6005 are used to hold the single-axis motor 6001 and to enhance the fixing strength of the single-axis motor 6001.

Assembly of an Apparatus Having in-Plane and Out-of-Plane Motions

An assembly of the light sensing apparatus according to one embodiment of the present application is described as follows. Referring to FIGS. 1 and 2 again, a thin glue layer (not shown) is applied or coated on the top surface 7042 of the additional plate 7041 and on the base plate frame 853 of the base plate 851 of the out-of-plane motion motor 7040. Attach the in-plane motion motor 7030 to the out-of-plane motion motor 7040 by attaching the circuit board 7033 to the base plate frame 853 and at the same time making the second bottom surface 1551 of the lead frame 7032 to be forced to contact the top surface 7042 of the additional plate 7041 with an assistance of a jig or tooling. The sequences of the assembly may vary depending on the optimization of the assembly process. After that, a high temperature curing process is required for fixing the in-plane motion motor 7030 and the out-of-plane motion motor 7040 permanently. Then the application device 7010, such as a filter allowing lights having wavelengths within a predetermined range to pass therethrough, is placed on the first circuit board 7033. If the application device 7010 is a visible light filter, the incoming lights having wavelength within the range of the visible light are transmitted through the application device 7010. For the camera application, the visible light filter is chosen. For different application, if the application device 7010 is an infrared radiation filter, incoming lights having wavelengths within the range of IR are transmitted through the infrared radiation filter.

A controller, which is not shown in the FIG. 1, is provided to electrically connect to the out-of-plane motion motor and the in-plane motion motor and control the movement of each of the single-axis motors 6002 and the in-plane motion actuator 7031.

After assembly, a light sensing apparatus 7000 having functions of optical image stabilization, auto focus and super resolution with 6 degree-of-freedom (DOF) movement ability according to one embodiment of the present application is constructed. The optical image stabilization is implemented by the compensation provided by the in-plane motion motor 7030 in the plane that the functional device 7020 lies in and by the four single-axis motors 7045 in the out-of-plane motion motor 7040 in the direction vertical to the plane that the functional device 7020, such as a CMOS image sensor, lies in and/or rotate in the pitched or rolled direction. The auto-focus function is implemented by the displacement of the four single-axis motors 7045 in the out-of-plane motion motor 7040 in the direction vertical to the plane that the functional device 7020 lies in. The super resolution function is implemented by the movement incrementally moved by the in-plane motion motor 7030 in a plane that the image sensing apparatus lies in. When the light sensing apparatus 7000 is used for the camera application, the superposition and synthesis of images taken with the incremental movement in a scale of being from sub-micrometers to micrometers can form the image with super resolution. If the optical image stabilization and auto focus functions are also included, a camera with multi-functions including optical image stabilization, auto focus and super resolution are fulfilled. This kind of camera using MEMS actuators with 6 DOF motions having the advantages of impact size, low cost, precise motion control, and low power consumption is provided by the present invention, and is impossible to achieve by the prior art.

In addition to the utilization of four single-axis motors 7045, one, two three or more single-axis motors 7045 can be used in the out-of plane motion motor 7040 according to another embodiment of the present invention. For example, when only one single-axis motor 7045 are used in the out-of-plane motion motor 7045, only the movement in one direction vertical to the plane that the functional device 7020 lies in can be implemented. When two or three single-axis motors 7045 are used, both of the vertical movement and a tilt movement can be implemented.

Accordingly, according to another embodiment of the present invention, when three single-axis motors 7045 are used, an apparatus 7000 having in-plane and out-of-plane motions can also be provided. FIGS. 1-3 and 10A-10B can still be referred with a difference that three single-axis motors 7045 rather than four of them are used. The apparatus 7000 includes an in-plane motion motor capable of moving an object in a first set of three degrees of freedom, i.e. moving in two transversal directions and one yawed rotational direction, with respect to a reference plane 160; and an out-of-plane motion motor 7040 supporting thereon the in-plane motion motor 7030, and including three single-axis motors 7045. Each of the three single-axis motors 7045 has an actuating end 855; and the three actuating ends cooperatively enable the reference plane to move in a second set of three degrees of freedom, i.e. moving in a vertical direction and two tilt directions. The object that can be further included in the apparatus 7000 can be an application device 7010 configured for an application function. The application device 7010 is mounted on the in-plane motion motor. The application device 7010 configured for an application function can be a filter or a lens, and the application function is to allow lights having wavelengths within a predetermined range to pass therethrough.

The in-plane motion motor 7030 includes a functional device 7020 such as a sensor configured for sensing a light; a first circuit board 7033 having a first bottom base 7034 with a central cavity 7035 and a first circuit board frame 7037 disposed thereon, where the first bottom base 7034 has a first bottom surface 1521; a lead frame 7032 is disposed inside the central cavity 7035, and has a second bottom surface 1551 and four hinges 1552; and an in-plane motion motor 7031 having a movable inner frame 1571 and a fixed outer frame 1572. The movable inner frame 1571 moves along at least one of two directions perpendicular to each other and parallel to the first bottom surface 1521. The application device 7010 is disposed on the first circuit board frame 7033.

The out-of-plane motion motor 7040 includes a base plate 851 having a base plate surface 852 and a base plate frame 853 disposed on a periphery of the base plate surface 852. Three single-axis motors 7045 are disposed on the base plate surface 852, each of which moves along a specific direction parallel to each other and parallel to a normal direction of the base plate surface 852. The first bottom surface 1521 is attached to the base plate frame 853. The second bottom surface 1551 is attached to the three actuating ends 855. An additional plate 7041 can also be introduced between the second bottom surface 1551 and the three actuating ends 855. Accordingly, the three actuating ends on three single-axis motors 7045 of the apparatus 7000 cooperatively enable the reference plane 160 to be capable of moving in another three degrees of freedom.

FIG. 18 is a block diagram showing a method for manufacturing an apparatus having in-plane and out-of-plane motions according to one embodiment of the present invention. As shown in FIGS. 1-3 and 18, the method includes the steps of Step S1920: providing an in-plane motion motor 7030 capable of moving in three degrees of freedom with respect to a reference plane 160 for mounting thereon a functional device 7020 for performing the application function; Step S1930: providing an out-of-plane motion motor 7040 capable of moving in at least another one degree of freedom when only one single-axis motor 7045 is disposed in the out-of-plane motion motor 7040, or capable of moving in four degrees of freedom when four single-axis motor 7045 are disposed in the out-of-plane motion motor 7040; Step S1940: attaching the first bottom surface 1521 of the circuit board 7033 of the in-plane motion motor 7030 to the base plate frame 853 of the out-of-plane motion motor 7040; and Step S1950: disposing the second bottom surface 1551 of the lead frame 7032 above the actuating end(s) of the single axis motor(s) 7045 of the out-of-plane motion motor 7040. Accordingly, the in-plane motion motor 7030 and the out-of-plane motion motor 7040 are attached. The method can further comprises the step of Step S1910: providing an application device 7010 configured for an application function, such as a filter for allowing the light having wavelengths within a predetermined range to pass therethrough before Step S1920.

FIG. 19 is a block diagram showing a process of Step S1920 in FIG. 18 for providing an in-plane motion motor according to one embodiment of the present invention. As shown in FIGS. 1-3 and 18-19, the process of Step S1920 in FIG. 18 includes the sub-steps of Step S1911: providing a functional device (such as a sensor) 7020 configured for sensing a light; Step S1912: providing a circuit board 7033 having a first bottom base 7034 having a central cavity 7035 and a first bottom surface 1521, and a circuit board frame 7037 disposed on the first bottom base 7034; Step S1913: disposing a lead frame 7032 inside the central cavity 7035, wherein the lead frame 7032 has a second bottom surface 1551 and four first hinges 1552; and Step S1914: installing an in-plane motion actuator 7031 having a movable inner frame 1571 and a fixed outer frame 1572 on the lead frame 7032. As also shown in FIG. 2, the four flexible hinges 1552 are disposed at four corners of the lead frame 7032 respectively, and the first bottom base 7034 of the circuit board 7033 has four notches 7036 extending from four corners of the central cavity 7035 respectively, and the four flexible hinges 1552 are correspondingly fitted and welded to the four notches 7036.

FIG. 20 is a block diagram showing a process of Step S1930 in FIG. 18 for providing an out-of-plane motion motor according to one embodiment of the present invention. As shown in FIGS. 9A, 9B and 20, the Step S1930 includes the sub-steps of Step S1921: providing a base plate 851 having a base plate surface 852 and a base plate frame 853 disposed on a periphery of the base plate surface 852; and Step S1922: disposing on the base plate surface 852 having a normal direction at least one single-axis actuator 854, which has an actuating end 855 moving along a direction parallel to the normal direction of the base plate surface 852. The numbers of the single-axis actuators 854 can be one, two, three or four, depending on the motions that the out-of-plane motion motor requires to provide.

FIG. 21 is a block diagram showing a method for assembling an in-plane motion motor with an out-of-plane motion motor according to another embodiment of the present invention. In this case, an addition plate 7041, which is not used in the method shown in FIGS. 18-20, is disposed between the four actuating ends 855 of the singe-axis motor 7045 and the second bottom surface 1551 of the lead frame 7032. As shown in FIGS. 1-3 and 22, after the Step S1940 which is the same as that as shown in FIG. 18, the method includes the steps of Step S1950a: attaching an additional plate 7041 to the four actuating ends 855 of the single-axis actuator 7045; and Step S1960: attaching the second bottom surface 1551 of the lead frame 7032 to the additional plate 7041. Accordingly, the in-plane motion motor 7030 and the out-of-plane motion motor 7040 are attached.

FIG. 22 is a block diagram showing a bonding process for electrically connecting the lead frame, the circuit board and the functional device, electrically connecting the lead frame to the circuit board, electrically connecting the in-plane motion actuator to the lead frame, and electrically connecting the sensor to the movable inner frame of the in-plane motion actuator, as shown in FIGS. 1-3 according to one embodiment of the present invention. As shown in FIGS. 1-3 and 22, the bonding process includes the sub-steps of Step S2311: providing a jig; Step S2312: disposing the circuit board 7033, the lead frame 7032, and the functional device (such as a sensor) 7020 onto the jig; Step S2313: electrically connecting the lead frame 7032 to the circuit board 7033; Step S2314: electrically connecting the in-plane motion actuator 7031 to the lead frame 7032; and Step S2315: electrically connecting the functional device 7020 to the movable inner frame 1571 of the in-plane motion actuator 7031. Accordingly, all of the above components are electrically connected. The bonding process can be a wire bonding process, which can be one of a welding process, a solder paste process and a combination thereof.

FIG. 23 is a block diagram showing a method for manufacturing an apparatus having in-plane and out-of plane motions according to another embodiment of the present invention. As shown in FIGS. 1-3, 9A, 9B and 23, the method includes steps of Step S2420: providing an in-plane motion motor 7030 capable of moving in a first set of three degrees of freedom with respect to a reference plane 160 for mounting thereon the application device 7010; Step S2430: providing an out-of-plane motion motor 7040 capable of moving in a second set of three degrees of freedom and having four single-axis motors 7045, a base plate surface 852 and supporting thereon the in-plane motion motor 7030; Step S2440a: attaching an additional plate 7041 having a top surface 7042 to the four actuating ends 855; and Step S2450: attaching the application device 7010 to the circuit board frame 7037. The method can further includes Step S2410: providing an application device 7010 configured for an application function before Step S2420. If the application device 7010 is a filter or a lens for allowing a light having wavelengths within a predetermined range to pass therethrough, the apparatus can be a light sensing device having in-plane and out-of plane motions.

Accordingly, the present invention also provides a method for manufacturing an apparatus having in-plane and out-of plane motions by a simple way of assembling the application device, the function device, the in-plane motion motor and the out-of-plane motion motors with assistance of a proper jig. The in-plane motion provides a first set of three degrees of freedom, and the out-of-plane motion provides a second set of three degrees of freedom differing from the first set of three degrees of freedom.

While the present disclosure has been described in terms of what is presently considered to be the most practical and preferred embodiments, it is to be understood that the present disclosure need not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A light sensing apparatus, comprising:
a sensor configured for sensing a light;
an in-plane motion motor, including:
a circuit board having a first bottom base with an central cavity and a circuit board frame disposed thereon, wherein the first bottom base has a first bottom surface;
a lead frame disposed inside the central cavity and having a second bottom surface; and
an in-plane motion actuator configured to dispose the sensor thereon and having a movable inner frame and a fixed outer frame both allocated in a reference plane, wherein the movable inner frame moves along at least one of two directions perpendicular to each other and parallel to the first bottom surface; and
an out-of-plane motion motor, including:
a base plate having a base plate surface and a base plate frame disposed on a periphery of the base plate surface;
four single-axis actuators disposed on the base plate surface, each of which has an actuating end, and each of which moves the respective actuating end along a direction perpendicular to the base plate surface, wherein:
the first bottom surface is attached to the base plate frame, and the second bottom surface is attached to the four actuating ends.

2. The light sensing apparatus according to claim 1, wherein the in-plane motion actuator further comprises:
a substrate having a first cavity;
an anchor disposed on the substrate, and is surrounded by the movable inner frame, and
an elastic element connecting the movable inner frame and the anchor, and enabling the movable inner frame to suspend over the substrate, wherein:
the first cavity has a first area, the movable inner frame has a second projecting area, and the first area and the second projecting area have an overlapping portion.

3. The light sensing apparatus according to claim 1, wherein a plurality of bonding pads are disposed at a peripheral of the movable inner frame, and adjacent to and electrically connected to the flexible elements.

4. The light sensing apparatus according to claim 3, wherein the substrate further includes a second cavity formed thereon, and located under the bonding pads.

5. The light sensing apparatus according to claim 1, wherein each of the four single-axis actuators further comprises:
a substrate having a cavity;
a first fixed electrode structure fixed on the substrate;
an elastic linkage; and
a movable electrode structure connected to the substrate through the elastic linkage, wherein:
the cavity has a first area;
at least one of the first fixed electrode structure and the movable electrode structure has a second projection area on the substrate; and
the first area and the second projection area overlap.

6. The light sensing apparatus according to claim 5, wherein the first fixed electrode structure and the movable electrode structure form a capacitor, the substrate has an electronic element, the substrate has a front surface and a rear surface, the cavity extends through the front and the rear surfaces, and the elastic element is a main hinge, the main hinge has a first end, a center point and a second end, and the first and the second ends are fixed on the substrate.

7. The light sensing apparatus according to claim 5, further comprising a second fixed electrode structure formed on the substrate and a support arm connected to the first fixed electrode structure, wherein each of the at least one position sensing capacitor is formed by the movable electrode structure and the second fixed electrode structure formed on the substrate, the at least one position sensing capacitor is disposed above one of the cavity and a second cavity of the substrate, and the support arm has a fifth end and a sixth end, and each of the fifth and the sixth ends is fixed on the substrate by an anchor.

8. The light sensing apparatus according to claim 1, wherein the lead frame further comprising four flexible hinges disposed at four corners thereof, and the first bottom base has four notches extend from four corners of the central cavity respectively, and the four flexible hinges are correspondingly fitted and welded to the four notches.

9. The light sensing apparatus according to claim 1, further comprising an additional plate having a top surface, and disposed between the second bottom surface and the four actuating ends.

10. The light sensing apparatus according to claim 9, wherein a glue layer is applied on the top surface of the additional plate and the base plate frame.

11. The light sensing apparatus according to claim 1, further comprising a filter disposed on the circuit board frame and allowing a range of wavelengths in the light passing therethrough.

12. The light sensing apparatus according to claim 11, wherein the filter allows wavelengths in a range of visible light to pass therethrough.

13. The light sensing apparatus according to claim 1, further comprising a first set of wires bonded between the in-plane motion actuator and the lead frame, and a second set of wires bonded between the lead frame and the circuit board.

14. An apparatus having in-plane and out-of-plane motions, comprising
an application device configured for an application function;
an in-plane motion motor mounting thereon the application device and capable of moving in three degrees of freedom with respect to a reference plane; and
an out-of-plane motion motor supporting thereon the in-plane motion motor, and including three single-axis actuators, wherein:
each of the three single-axis actuators has an actuating end; and
the three actuating ends cooperatively enable the reference plane to move in another three degrees of freedom.

15. The apparatus having in-plane and out-of-plane motions according to claim 14, wherein the application device is one selected from a group consisting of a mirror, a filter and a sensor, and the application function is one selected from a group consisting of a scanning function, a filtering function and a sensing function.

16. The apparatus according to claim 14, wherein the in-plane motion motor includes:
a sensor configured for sensing a light;
a circuit board having a first bottom base with an central cavity and a circuit board frame disposed thereon, wherein the first bottom base has a first bottom surface, and the application device is disposed on the circuit board frame;
a lead frame disposed inside the central cavity, and having a second bottom surface and four flexible hinges; and
an in-plane motion actuator configured to dispose the sensor thereon and having a movable inner frame and a fixed outer frame, wherein the movable inner frame moves along at least one of two directions perpendicular to each other and parallel to the first bottom surface.

17. The apparatus according to claim 16, wherein the in-plane motion motor further includes a connecting component being one of a flexible circuit board and a set of soft electrical linkages connecting between the movable inner frame and the fixed outer frame, wherein the set of soft electrical linkages provides mechanical and electrical connections, and the flexible circuit board provides mechanical, electrical connection and thermal connections.

18. The apparatus according to claim 14, wherein the out-of-plane motion motor includes:
a base plate having a base plate surface and a base plate frame disposed on a periphery of the base plate surface, wherein:
the three single-axis actuators are disposed on the base plate surface, each of which moves along a direction parallel to each other and perpendicular to the base plate surface,
the first bottom surface is attached to the base plate frame; and
the second bottom surface is attached to the three actuating ends.

19. An apparatus having in-plane and out-of-plane motions, comprising
an application device configured for an application function;
an in-plane motion motor mounting thereon the application device and capable of moving in three degrees of freedom with respect to a reference plane; and
an out-of-plane motion motor supporting thereon the in-plane motion motor, and including a first single-axis actuator, wherein:
the first single-axis actuator has an actuating end, and the actuating end enables the reference plane to move in a fourth degree of freedom other than the three degrees of freedom.

20. The apparatus according to claim 19, further comprising another two single-axis actuators moving along the direction, wherein each of the another two single-axis actuators has another actuating end, and the actuating end and the two another actuating ends cooperatively enable the reference plane to be capable of moving in a fifth and a sixth degrees of freedom.
